(19) United States
(12) Patent Application Publication
(10) Pub. No.: US 2010/0263914 A1
(43) Pub. Date: Oct. 21, 2010

(54) Floating Metal Elements in a Package Substrate

(75) Inventors: Jack M. Yao, San Diego, CA (US); Ruey Kae Zang, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/425,184

(22) Filed: Apr. 16, 2009

(51) Int. Cl. H05K 1/00

(52) U.S. Cl. 174/250

(57) ABSTRACT

A plurality of metal elements formed in an electronic package. The electronic package includes an electronic substrate and a plurality of metal elements disposed in a layer of the substrate. The plurality of metal elements do not serve an electrical function in the layer. Also, each of the plurality of metal elements is floating in the layer. In another embodiment, a method for optimizing the design of a package substrate is provided. The method includes identifying a space in a layer of the substrate that is free of metal and forming a plurality of metal elements in the identified space, where the plurality of metal elements do not serve an electrical function.

### FIELD OF DISCLOSURE

This disclosure relates generally to an electronic package, and in particular to an electronic package having a substrate with a plurality of floating metal elements disposed in a layer of the substrate.

### BACKGROUND

In electronic packaging, trace routing on a package substrate tends to have an impact on overall circuit performance. The design of the package often requires specific spacing between different signal traces and planes for achieving a desired level of performance. The spacing constraints can often improve circuit performance, but may also negatively affect the manufacturability of the package.

In a conventional package structure, a package substrate is provided with one or more layers. To improve reliability, it is desired that each layer have a certain percentage of copper with respect to the size of the package substrate. When the required spacing between signal traces is substantial, the percentage of copper in the layer is thereby reduced and the required amount of copper is not achieved for reliability purposes. As a result, there can be reliability issues associated with the package substrate.

Package assembly can also be negatively affected by a reduced amount of copper in a layer of the package substrate. It is necessary for the package substrate to maintain a certain flatness during assembly, and when this is not achieved, the package substrate cannot be used for assembly processes such as die attachment, package solder ball/pin attachment, flip chip mold underfill, flip chip capillary underfill, and flip chip bump metallic bonding between die and package substrate during reflow.

Also, during substrate manufacturing processes, it is necessary for the design of the package to include a specific amount of copper to prevent the substrate from warping. As an example, it may be desired that each layer have at least 50% metal coverage. This can be problematic in RF packaging designs when the metal coverage in a layer may only be about 30%.

Another problem encountered in a package substrate is that the design of the package is finalized and the electrical performance of the design has been confirmed, but there is not the desired amount of copper in the layer of the package substrate. Since the design is finalized and electrical performance is confirmed, it is undesirable to change the design of the package by moving signal traces and affect the electrical performance of the overall system. However, by not increasing the metal content in the layer, the package substrate can bend, crack, and/or warp.

Therefore, it would be desirable to optimize the design of an electronic package by increasing the metal content in a layer of a package substrate without affecting the electrical performance of the overall system.

### SUMMARY

For a more complete understanding of the present disclosure, reference is now made to the following detailed description and the accompanying drawings. In an exemplary embodiment, an electronic package is provided that includes an electronic substrate and a plurality of metal elements disposed in a layer of the substrate. The plurality of metal elements do not serve an electrical function in the package. The plurality of metal elements can be arranged in a two-dimensional or three-dimensional array. Each of the plurality of metal elements can be substantially the same shape and be made of copper, aluminum, silver, or gold. Alternatively, the material of the plurality of metal elements can be the same material used for signal lines in the layer. The plurality of metal elements can minimize the effects of capacitance, inductance, and resistance in the substrate. The plurality of metal elements can be disposed in the layer of the substrate to increase the percentage of metal in that layer to achieve a threshold density, for example, 80%. In one embodiment, each of the plurality of metal elements is free from contacting another element in the layer.

In another embodiment, a method of increasing the content of metal in a layer of an electronic package is provided. The method includes identifying an area in the layer that does not include a desired amount of metal. The identified area is filled with a plurality of metal elements such that the plurality of metal elements do not serve an electrical function. The method can further include arranging each of the plurality of metal elements in an array. The plurality of metal elements can be substantially the same shape and be made of copper, aluminum, gold, or silver. Each of the plurality of metal elements is spaced apart in the layer. The method can also include choosing the shape of each of the plurality of metal elements based on the size and configuration of the identified area.

In a different embodiment, a layer in an electrical package is provided. The layer includes an area that comprises signal lines and an area with a plurality of metal elements disposed therein. The plurality of metal elements can be positioned in a pattern in the layer. The plurality of metal elements also do not serve an electrical function and each of the plurality of metal elements can be formed to have substantially the same shape.

### BRIEF DESCRIPTION OF THE DRAWINGS

FIG. 1 is a top planar view of a package substrate layer having signal lines;

FIG. 2 is a top planar view of the package substrate layer of FIG. 1 with a plurality of metal elements;

FIGS. 3-12 are planar views of exemplary patterns and shapes of metal elements;

FIG. 13 is a flow diagram of an exemplary embodiment for designing a package substrate with a plurality of metal elements; and

FIG. 14 is a block diagram showing an exemplary wireless communication system in which a package substrate with a plurality of metal elements may be advantageously employed.

### DETAILED DESCRIPTION

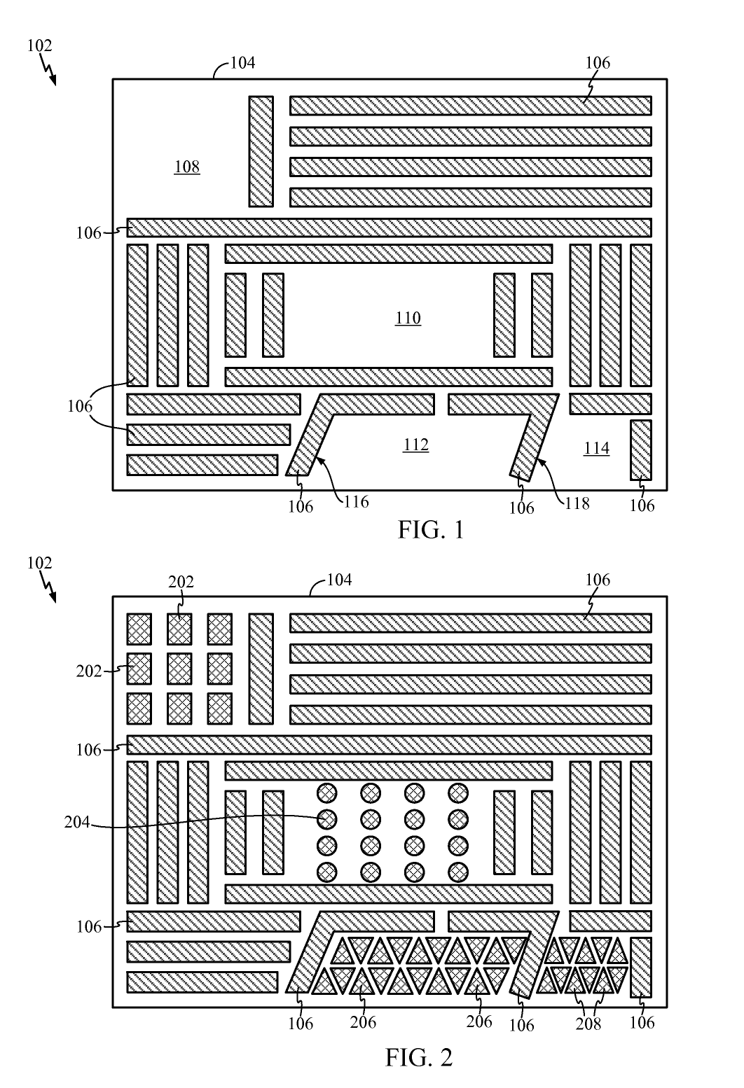

Referring to the exemplary embodiment shown in FIG. 1, a design of an electrical package is provided. The electrical package includes a package substrate 102. Near the top of the package, solder balls, bumps, or bond wires (not shown) can be provided for coupling to a chip. Likewise, at the bottom of the package, additional solder balls, pins, or Land Grid Array pads (not shown) can be provided for coupling the substrate 102 to a printed circuit board (PCB).

The substrate 102 can include a plurality of substrate layers (hereinafter “layer”). In FIG. 1, for example, a layer 104 is shown having multiple signal lines 106 disposed in the layer. Each signal line 106 is provided for conducting a signal. In this embodiment, the electrical performance of the overall system has been analyzed and categorized. Thus, it is undesirable to change the routing of any of the signal lines 106. In addition, the spacing of the signal lines has been arranged to achieve the desired performance level. As such, the design of the package for electrical performance is complete, but it is necessary for each layer to have a minimum amount of metal for the stability and rigidity of the substrate.

Since a majority of the package is formed of dielectric material, it may be desirable to increase the amount or percentage of metal in each layer. To do so, voids or open spaces between signal lines in the layer are identified and a plurality of metal elements can be formed therein. In FIG. 1, for example, the layer 104 includes a first space 108, a second space 110, a third space 112, and a fourth space 114 between signal lines 106. To achieve a desired level of metal content in the layer 104, a plurality of metal elements can be formed in each area (i.e., 108, 110, 112, and 114).

Referring to FIG. 2, the layer 104 is shown with a plurality of metal elements formed therein. For example, in the first space 108, a plurality of rectangular metal elements 202 can be formed in the space 108. In the second space 110, a plurality of circular metal elements 204 can be formed therein. Likewise, in the third space 112 and fourth space 114, a plurality of triangular metal elements 206 and 208, respectively, can be formed therein. The plurality of metal elements can be formed by a similar process as the other metal content is formed in the layer 104 such as photomasking and etching. Other processes known to the skilled artisan can also be used to form the plurality of metal elements in the spaces.

Each metal element can be made of copper, aluminum, gold, silver, or any other metal used to form the signal lines 106 in the layer. Also, the plurality of metal elements can comprise any number of individual elements. The number of metal elements that fills a space can be based upon the size and shape of the space. For example, in FIG. 2, the first space 108 in the layer 104 is rectangularly or squarely shaped. As such, the plurality of metal elements 202 that are formed in the first space 108 are rectangular. In this arrangement, the plurality of rectangular metal elements 202 consume a substantial amount of area within the space 108 and thus effectively increase the metal content in the layer 104.

The plurality of metal elements can be arranged in a repeated pattern such as a two-dimensional or three-dimensional array. Again, the shape of the metal elements and the pattern of the plurality of metal elements can depend on the size and shape of the space in the layer 104. In the second space 110 of the layer 104, the plurality of metal elements 204 are circular in shape but are arranged in a rectangular, two-dimensional array to substantially fill the space 110. The third space 112 and fourth space 114 are configured by the signal lines 106 to include angled edges 116, 118. To fill the most area within each space 112 and 114, the plurality of metal elements 206, 208 that are formed in each space 112, 114, respectively, are triangular. The shape of each of the plurality of metal elements can be varied to achieve the desired level of metal content in the layer 104.

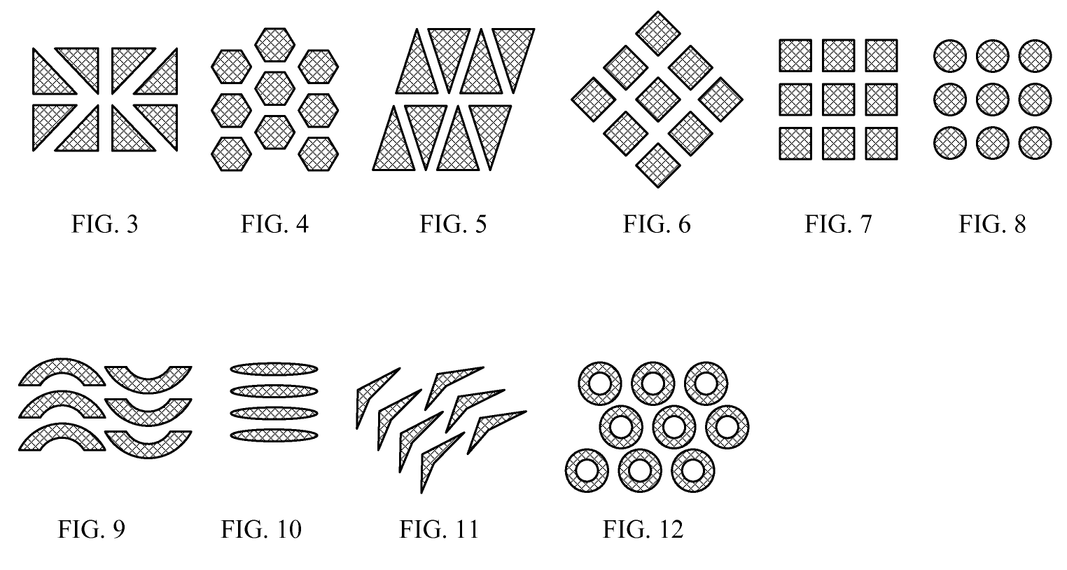

In FIGS. 3-12, different exemplary shapes of metal elements are provided which can be formed in spaces of layers to provide a desired metal content or density in the layer. Other arbitrary shapes not provided in FIGS. 3-12 can also be used and one skilled in the art can creatively form any shape of metal element to achieve the desired amount of metal in a layer.

The size of each metal element in a plurality of metal elements can depend on the size and shape of the space in the layer. In one embodiment, for example, each metal element can be about 30 μm×30 μm or larger. Each metal element is spaced from an adjacent metal element such that no metal element within an array is in contact or couples with another metal element. In other words, each metal element is “floating” independently in the layer.

As described above, when the electrical performance of the overall system is confirmed, it is desirable that the plurality of metal elements have no significant impact on the electrical performance of the system. Each metal element has a capacitance, and by arranging the plurality of metal elements in a repeated pattern or array (i.e., series), the overall capacitance is reduced relative to a single large metal element. The effective capacitance can therefore be reduced substantially by arranging the plurality of small metal elements in an array. This aspect makes it desirable to form small individual metal elements in a repeated pattern with other metal elements.

It is also desirable to form small independent metal elements so there is very little inductance attributed to each element. Further, since the plurality of metal elements are “floating” in the layer and do not couple to any signal line, the metal elements do not contribute any resistance to the overall system. Therefore, since the plurality of metal elements contribute little to no capacitance, inductance, or resistance, there is no substantial electrical impact to the system.

However, while there is essentially no impact to the electrical performance of the overall system, the plurality of metal elements can provide mechanical benefits to the package. Since most of the package contains dielectric material, the robustness of the package can be improved by the plurality of metal elements to prevent bending or cracking. The metal elements can improve the substrate manufacturing yield, substrate stiffness, and resistance to substrate warpage. Additional benefits of adding metal elements to the substrate include improving the overall package assembly. The substrate should have a specified flatness for die attachment, flip chip bump metallic bonding between die and package substrate during reflow, flip chip capillary underfill, flip chip mold underfill, and package solder ball/pin attachment. Each of these assembly processes can be difficult to perform without a flat substrate. The metal elements also can improve the package coplanarity.

In the substrate manufacturing process, it is desirable to have a certain metal coverage in a substrate layer to resist warpage. The percentage of metal required in the layer of the package can depend on the application and/or vendor. In RF applications, for example, at least 50% metal coverage may be desired in the layer. In other packaging applications, about 80% metal coverage may be desired. In packaging designs without metal elements, for example, there may only be 20% metal coverage in a given layer. Therefore, forming these “floating” metal elements can achieve the desired amount of metal coverage for the layer in a package. The metal elements can be selected to be large enough to achieve the desired metal density of the layer, but small enough to not have a significant impact on the electrical performance of the system.

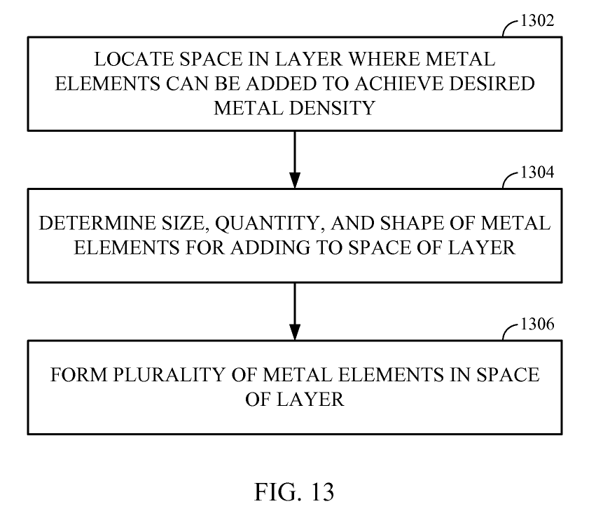

In FIG. 13, an exemplary method of designing a layer in a package substrate with a plurality of metal elements is provided. This method assumes that the design and layout of signal lines has been completed in the layer. In an alternative embodiment, the method can include designing the routes of signal lines in the layer and forming the signal lines according to the design. Once the signal routing is complete and the desired electrical performance of the system is achieved, the method includes determining how much metal can be added to each layer to achieve the desired metal coverage amount. For example, the layer may have 20% metal coverage and the desired coverage is 80% metal coverage. At block 1302, available space in the layer is identified in which a plurality of metal elements can be formed.

Once available space is identified for forming the plurality of metal elements, the type of metal element is determined. At block 1304, for example, the size, quantity, and shape of each metal element is determined. To make this determination, the size and configuration of the identified space in the layer to be filled is evaluated. Depending on the configuration of the identified space, the shape of the plurality of metal elements can be selected. If the space is configured as a diamond, for example, the diamond-shaped metal elements shown in FIG. 6 can be selected for filling the given space. Further, the plurality of diamond-shaped metal elements can be arranged in a diamond-shaped pattern to most completely fill the space with metal. As another example, if the space is configured as a square the plurality of square-shaped metal elements of FIG. 7 or circular-shaped metal elements of FIG. 8 can be selected for filling the space. It is desirable to form each of the plurality of metal elements to have sufficient size so that the desired metal content for the layer can be achieved. Besides wanting to the fill the available space with metal, however, ease of manufacturing the metal elements can also be considered when determining the shape and size of the metal element.

In addition to manufacturing considerations, the size of the plurality of metal elements is also an important consideration with regard to electrical performance impact. While it may be easier to manufacture fewer individual metal elements and a smaller quantity of metal elements having greater size may consume more area within the available space, a larger quantity of smaller metal elements can reduce the effective capacitance in the system. Since it is important that the plurality of metal elements have no substantial impact on the electrical performance of the package, the shape and size of each metal element also depends on the impact to the electrical performance of the package. Thus, there can be a size trade-off between metal content and ease of manufacture considerations versus electrical impact considerations.

Also, the plurality of metal elements that fill a given space can be formed in a repeated pattern such as a two-dimensional or three-dimensional array. Each metal element in the array can be formed of the same shape and size to reduce capacitance. The pattern can be selected based on the size and configuration of the space in the layer and the desired metal content, manufacturability, and impact on electrical performance of the package.

At block 1306, the plurality of metal elements are formed in the identified space of the layer. The plurality of metal elements can be formed by photomasking and etching the metal elements in the layer or any other known process. The process of forming the metal elements can be the same as the process for forming the signal lines in the layer and therefore no special process may be required. The metal elements can be formed at the same time as the signal lines are formed or at an alternative time. It is desirable that each metal element not contact or be coupled to another metal element or any other object in the layer. In other words, each metal element is “floating” in the layer.

The method can also include confirming that the total amount of metal added to the layer achieves the desired metal coverage for manufacturability. This may include confirming the desired metal coverage for coplanarity and warpage recommendations.

After the plurality of metal elements have been formed, the electrical package can be made ready for installation in an electronic device such as a cell phone, computer, personal digital assistant (PDA), and the like.

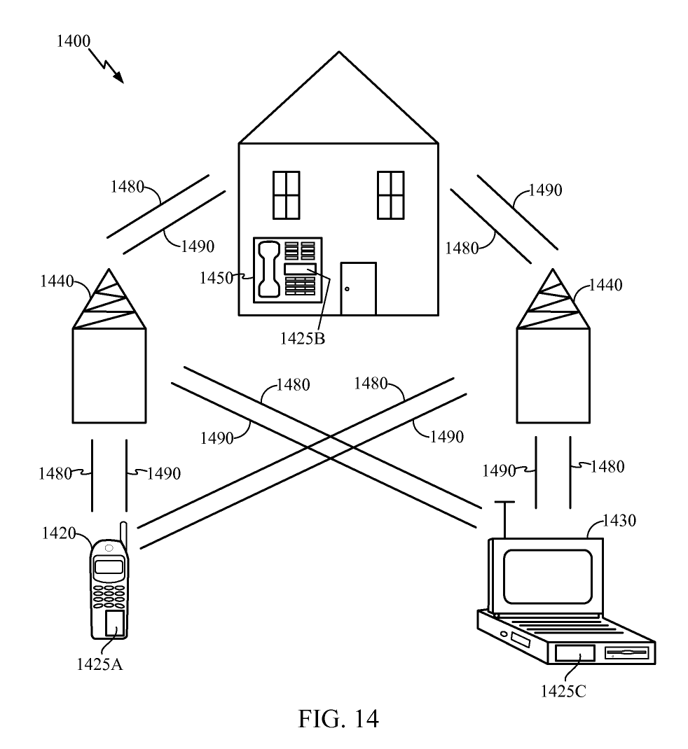

FIG. 14 shows an exemplary wireless communication system 1400 in which an embodiment of a package substrate with a plurality of “floating” metal elements may be advantageously employed. For purposes of illustration, FIG. 14 shows three remote units 1420, 1430, and 1450 and two base stations 1440. It should be recognized that typical wireless communication systems may have many more remote units and base stations. Any of remote units 1420, 1430, and 1450 may include a package substrate with a plurality of “floating” metal elements such as disclosed herein. FIG. 14 shows forward link signals 1480 from the base stations 1440 and the remote units 1420, 1430, and 1450 and reverse link signals 1490 from the remote units 1420, 1430, and 1450 to base stations 1440.

In FIG. 14, remote unit 1420 is shown as a mobile telephone, remote unit 1430 is shown as a portable computer, and remote unit 1450 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 14 illustrates certain exemplary remote units that may include a package substrate with a plurality of “floating” metal elements as disclosed herein, the package substrate is not limited to these exemplary illustrated units. Embodiments may be suitably employed in any electronic device in which a package substrate with a plurality of “floating” metal elements is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. An electronic package, comprising:
an electronic substrate; and
a plurality of metal elements disposed in a layer of the substrate;
wherein, the plurality of metal elements do not serve an electrical function.

2. The electronic package of claim 1, wherein the plurality of metal elements form a repeated pattern in the layer.

3. The electronic package of claim 2, wherein the repeated pattern comprises a two-dimensional or three-dimensional array.

4. The electronic package of claim 2, wherein, in the repeated pattern, each of the plurality of metal elements comprises substantially the same shape and size.

5. The electronic package of claim 1, wherein each of the plurality of metal elements is made of the same material as signal lines in the layer.

6. The electronic package of claim 1, wherein the plurality of metal elements is sized to substantially reduce the effects of capacitance, inductance, and resistance in the substrate.

7. The electronic package of claim 1, wherein each of the plurality of metal elements is floating in the layer.

8. A method for optimizing the design of a package substrate, comprising:
identifying a space in a layer of the package substrate free of metal;
forming a plurality of metal elements in the identified space, wherein the plurality of metal elements do not serve an electrical function.

9. The method of claim 8, further comprising arranging the plurality of metal elements in a repeated pattern to maximize the amount of metal in the identified space.

10. The method of claim 9, wherein, in the repeated pattern, each of the plurality of metal elements comprises substantially the same shape and size.

11. The method of claim 8, further comprising forming the plurality of metal elements small enough to minimize the effects of capacitance.

12. The method of claim 8, further comprising forming the plurality of metal elements large enough to achieve a desired metal content threshold.

13. The method of claim 12, wherein the desired metal content threshold is about 50% or more.

14. The method of claim 8, wherein the plurality of metal elements comprises copper, aluminum, gold, or silver.

15. The method of claim 8, wherein each of the plurality of metal elements is floating in the layer.

16. The method of claim 8, further comprising determining the quantity, size, and shape of the plurality of metal elements to achieve a desired metal density in the identified space while having an insubstantial impact on the electrical performance of the package substrate.

17. The method of claim 16, further comprising selecting the quantity, size, and shape of the plurality of metal elements based on the size and shape of the identified space.

18. The method of claim 8, wherein the forming a plurality of metal elements comprises photomasking and etching.

19. A package substrate, comprising:
a plurality of floating metal elements arranged as a pattern in a layer of the substrate;
wherein, the plurality of floating metal elements do not serve an electrical function.

20. The layer of claim 19, wherein the pattern comprises a two-dimensional or three-dimensional array.
